(19) United States
(12) Patent Application Publication
(10) Pub. No.: US 2011/0062482 A1
(43) Pub. Date: Mar. 17, 2011

(54) Apparatus And Method For Enhancing Connectability In LED Array Using Metal Traces

(75) Inventors: Michael Solomensky, Sunnyvale, CA (US); Shane Harrah, Sunnyvale, CA (US); Rene Peter Helbing, Sunnyvale, CA (US)

(73) Assignee: Bridgelux, Inc., Sunnyvale, CA (US)

(21) Appl. No.: 12/690,387

(22) Filed: Jan. 20, 2010

(51) Int. Cl. H01L 33/00; H01L 21/50

(52) U.S. Cl. 257/99; 438/28; 257/E33.066; 257/E21.499

(57) ABSTRACT

A light-emitting device having multiple light-emitting diode (“LED”) dice organized in an array capable of configuring LED dice in series, parallel, and/or a combination of series and parallel via metal traces is disclosed. In one aspect, the light-emitting device includes a substrate, a dielectric layer, an LED array, and a metal trace. The dielectric layer, which is disposed over the substrate, provides electric insulation. The LED array capable of generating light is able to enhance flexibility of LED connections using a metal trace. The metal trace has a predefined shape configured to travel through the LED array for facilitating electric connections.

### FIELD

The exemplary aspect(s) of the present invention relates to lighting devices. More specifically, the aspect(s) of the present invention relates to light-emitting semiconductor fabrication with flexible LED connections capable of reconfiguring electrical connections of light emitting diodes (“LED”) dice.

### BACKGROUND

Solid-state light-emitting devices such as LEDs are attractive candidates for replacing conventional light sources such as incandescent and fluorescent lamps. LEDs typically have higher light conversion efficiencies than incandescent lamps, and have longer lifetime than conventional light sources. Certain types of LEDs, for instance, have higher light conversion efficiencies than fluorescent light sources and even higher conversion efficiencies have been demonstrated in the laboratory. For LEDs to be accepted in various lighting applications, it is important to optimize every step of the processing and achieve the highest efficiencies possible.

A physical characteristic associated with a conventional LED lighting system having multiple LED dice is performance variation in connection to the source of power supply. For example, LED dice connected in series tend to produce more flux for a fixed amount of current than the LED dice connected in parallel. As such, LED dice connected in series performs well for a fixed amount of current source with high voltage. Conversely, LED dice connected in parallel configuration tend to provide more flux with a power source that provides high current and low voltage than a power source with low current and high voltage. Accordingly, the performance of an LED lighting system can vary depending on the availability of the power source.

A problem associated with manufacturing a conventional LED light system is the lack of flexibility in LED connections after substrates are fabricated. In other words, changing the LED dice electrical connection after the substrates are fabricated is typically difficult. Due to the tight layout of a conventional LED light system, the flexibility of connecting LED dice in series and/or parallel is limited after the components are formed.

### SUMMARY

A light-emitting device having multiple LED dice organized in an array capable of flexibly configuring LED dice in series, parallel, and/or a combination of series and parallel via metal traces is disclosed. In one aspect, the light-emitting device includes a substrate, a dielectric layer, an LED array, and a set of metal traces. The dielectric layer, which is disposed over the substrate, provides electric insulation. The LED array capable of generating light is able to enhance flexibility of LED connections using one or more metal traces. The metal trace has a predefined shape configured to travel through the LED array for facilitating electric connections in multiple electrical configurations.

It is understood that other aspects of the present invention will become readily apparent to those skilled in the art from the following detailed description, wherein it is shown and described only exemplary configurations of an LED by way of illustration. As will be realized, the present invention includes other and different aspects and its several details are able to be modified in various other respects, all without departing from the spirit and scope of the present invention. Accordingly, the drawings and the detailed description are to be regarded as illustrative in nature and not as restrictive.

### BRIEF DESCRIPTION OF THE DRAWINGS

The exemplary aspect(s) of the present invention will be understood more fully from the detailed description given below and from the accompanying drawings of various aspects of the invention, which, however, should not be taken to limit the invention to the specific aspects, but are for explanation and understanding only.

FIG. 1 is a diagram illustrating a lighting system having multiple LED dice with reconfigurable connections in accordance with an aspect of the present invention;

FIG. 2 is a diagram illustrating a lighting system having three LED dice capable of providing reconfigurable connections in accordance with an aspect of the present invention;

FIG. 3 is a diagram illustrating a lighting system having three LED dice connected in series via a metal trace in accordance with an aspect of the present invention;

FIG. 4 is a diagram illustrating a lighting system having four LED dice connected in series via a Z-shaped metal trace in accordance with an aspect of the present invention;

FIG. 5 is a diagram illustrating a lighting system having multiple LED dice connected in series using a straight metal trace in accordance with an aspect of the present invention;

FIGS. 6A-B are diagrams showing alternative metal trace shapes used in LED array in accordance with an aspect of the present invention;

FIGS. 7A-C illustrate images showing LED lighting devices capable of reconfiguring LED connections using metal traces in accordance with an aspect of the present invention;

FIG. 8A illustrates an exploded view of a lighting system having an LED array using metal trace for flexible LED connections in accordance with an aspect of the present invention;

FIG. 8B illustrates images of a lighting system having an LED array using metal trace for facilitating flexible LED connections in accordance with an aspect of the present invention;

FIG. 9 is a flowchart illustrating a process of fabricating a lighting device having multiple LED dice and a metal trace for reconfigurable connections in accordance with an aspect of the present invention;

FIG. 10 is a conceptual cross-sectional view illustrating an exemplary fabrication process of an LED or LED devices;

FIG. 11 is a conceptual cross-sectional view illustrating an example of an LED with a phosphor layer;

FIG. 12A is a conceptual top view illustrating an example of an LED array that can be used with flexible LED connections in accordance with an aspect of the present invention;

FIG. 12B is a conceptual cross-sectional view of the LED array of FIG. 12A;

FIG. 13A is a conceptual top view illustrating an example of an alternative configuration of an LED array that can be used with flexible LED connections in accordance with an aspect of the present invention;

FIG. 13B is a conceptual cross-sectional view of the LED array of FIG. 13A; and

FIG. 14 shows exemplary lighting devices including LED devices using flexible LED connections in accordance with an aspect of the present invention.

### DETAILED DESCRIPTION

Aspects of the present invention is described herein in the context of a method, device, and apparatus of reconfiguring connections of light emitting diode (“LED”) dice organized in an array using one or more metal traces.

The present invention is described more fully hereinafter with reference to the accompanying drawings, in which various aspects of the present invention are shown. This invention, however, may be embodied in many different forms and should not be construed as limited to the various aspects of the present invention presented throughout this disclosure. Rather, these aspects are provided so that this disclosure will be thorough and complete, and will fully convey the scope of the present invention to those skilled in the art. The various aspects of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus (e.g., device) or method.

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower”, can therefore, encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items

Various aspects of an LED luminaire will be presented. However, as those skilled in the art will readily appreciate, these aspects may be extended to aspects of LED luminaries without departing from the invention. The LED luminaire may be configured as a direct replacement for conventional luminaries, including, by way of example, recessed lights, surface-mounted lights, pendant lights, sconces, cove lights, track lighting, under-cabinet lights, landscape or outdoor lights, flood lights, search lights, street lights, strobe lights, bay lights, strip lights, industrial lights, emergency lights, balanced arm lamps, accent lights, background lights, and other light fixtures.

As used herein, the term “light fixture” shall mean the outer shell or housing of a luminaire. The term “luminaire” shall mean a light fixture complete with a light source and other components (e.g., a fan for cooling the light source, a reflector for directing the light, etc.), if required. The term “LED luminaire” shall mean a luminaire with a light source comprising one or more LEDs. LEDs are well known in the art, and therefore, will only briefly be discussed to provide a complete description of the invention.

It is further understood that the aspect of the present invention may contain integrated circuits that are readily manufacturable using conventional semiconductor technologies, such as CMOS (“complementary metal-oxide semiconductor”) technology, or other semiconductor manufacturing processes. In addition, the aspect of the present invention may be implemented with other manufacturing processes for making optical as well as electrical devices. Reference will now be made in detail to implementations of the exemplary aspect(s) as illustrated in the accompanying drawings. The same reference indicators will be used throughout the drawings and the following detailed description to refer to the same or like parts.

An LED lamp includes multiple LED dice organized in an array which is capable of configuring LED dice in series, parallel, and/or a combination of series and parallel via one or more metal traces. In one aspect, the LED lamp includes a substrate, a dielectric layer, an LED array, and a metal trace. The dielectric layer, which is disposed over at least a portion of the substrate, provides electric insulation. The LED array capable of generating light is able to enhance flexibility of LED connections using one or more metal traces. The metal trace has a predefined shape configured to travel through the LED array to facilitate electric connections.

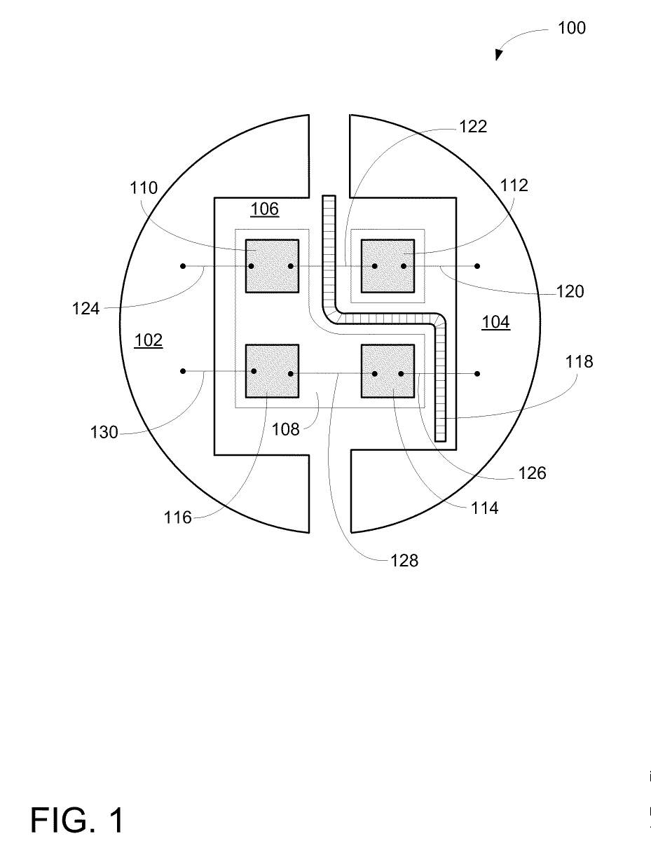

FIG. 1 is a diagram 100 illustrating a lighting system having multiple LED dice with reconfigurable connections in accordance with an aspect of the present invention. Diagram 100 includes an LED array, a substrate 108, a patterned dielectric layer 106, and a metal trace 118, wherein the LED array includes LED dice 110-116. LED dice 110-116 are coupled to terminals or pads 102-104 using bond wires 120-130. It should be noted that the underlying concept of the exemplary aspect(s) of the present invention would not change if one or more elements (or devices) were added to or removed from diagram 100.

The LED array, in one aspect, includes four (4) LED dice 110-116, wherein each LED die is a semiconductor diode capable of converting electrical energy to optical light. Note that the conversion of electrical energy to optical energy is also known as electroluminescence. The color of the light is generally based on the energy gap of the semiconductor used. The LED array is able to configure layout of LED dice 110-116 such as parallel or serial connections after the components are fabricated. Each LED die includes a first electrical contact and a second electrical contact capable of electrically coupling to conductive traces and/or pads. LED dice 110-116 are disposed or fastened over substrate 108.

Substrate 108 can be a metal substrate or dielectric substrate. The metal substrate, which is a conductive substrate, can be made of aluminum, nickel, copper, metal alloy, and/or a combination of electrical conductive materials. Alternatively, a dielectric substrate, which is a non-conductive substrate, can be made of non-conductive materials, such as ceramic, plastic, glass, and/or materials for making printed circuit board (“PCB”). As such, depending on applications, substrate 108 can be either made of conductive, non-conductive, or a combination of metal and dielectric materials.

Substrate 108, also known as reconfigurable LED array substrate, is formed with trenches that separate and define sections which house one or more electronic components such as LED dice 110-116. Trenches or traces provide wiring mechanism to facilitate electrical interconnections between individual components. In one example, substrate 108 further includes an integral reflector(s) shaped in a form of cavity (or cavities) to house LED die(s). Reflector cavity walls, for instance, can be optionally plated with reflective materials and/or filled with molding materials used for lens and/or encapsulant. In one aspect, substrate 108 is made of aluminum-aluminum oxide through applicable semiconductor manufacturing technologies such as Aluminum Oxide (“ALOX”) process. Depending on processing technologies, a metal substrate can satisfy manufacturing requirements as well as electrical interconnections, thermal limitations, and desirable mechanical properties. Dielectric layer 106, in one aspect, is disposed over metal substrate 108 to provide electric insulation. Multiple electrically conductive traces such as metal trace 118 can be subsequently disposed over dielectric layer 106. In one instance, dielectric layer 106 includes ALOX.

Metal trace 118, in one aspect, is made of electrically conductive materials, such as aluminum, copper, nickel, gold, or a combination of aluminum, copper, nickel, and gold, to facilitate movement of electrical current. Metal trace 118 is an S-shaped metal strip configured to travel through the LED array to enhance electric connectivity. For example, metal trace 118 passes through LED dice 110-116 in an LED array, as illustrated in FIG. 1, to enhance flexibility of electric connectivity. A function of metal trace 118 is to provide additional wire bond connection(s) thereby LED dice 110-116 can be flexibly reconfigured in a parallel connection, series connection, or a combination of series and parallel connections after the components are fabricated.

Referring back to FIG. 1, a first terminal of LED die 110 is connected to a first terminal of power source 102 via bond wire 124 and a second terminal of LED die 110 is connected to a first terminal of LED die 112 via bond wire 122. A second terminal of LED die 112 is connected to a second terminal of power source 104. While a second terminal of LED die 114 is connected to second terminal 104 via bond wire 126, a first terminal of LED die 114 is connected to a second terminal of LED die 116 via bond wire 128. A first terminal of LED die 116 is connected to the first terminal of power source 102 via bond wire 130. Note that the first terminal of power source 102 can be positive potential of a power supply and the second terminal of power source 104 can be negative potential of a power supply. The LED array has two (2) serial strings of LED dice wherein each string includes two LED dice. For example, LED dice 110-112 form the first series of LED dice while LED dice 114-116 form the second series connection of LED dice. The first series of LED dice 110-112 is in parallel with the second series of LED dice 114-116.

An advantage of having a metal trace(s) such as metal trace 118 is to provide different number of LED dice to generate a different combination of series and/or parallel connections depending on the specific customer's requirements. Note that the S-shaped metal trace 118 is for illustrated purposes, the underlying concept of the exemplary aspect(s) of the present invention would not change if metal trace 118 is in an H-shape, Z-shape, I-shape, and/or any other shapes or formations.

It should be noted that a metal trace disposed over a substrate can provide different LED interconnection patterns or layout. In addition, it is also advantageous to have a substrate having direct metal connection with low thermal resistance path between a die and a bottom surface of the substrate.

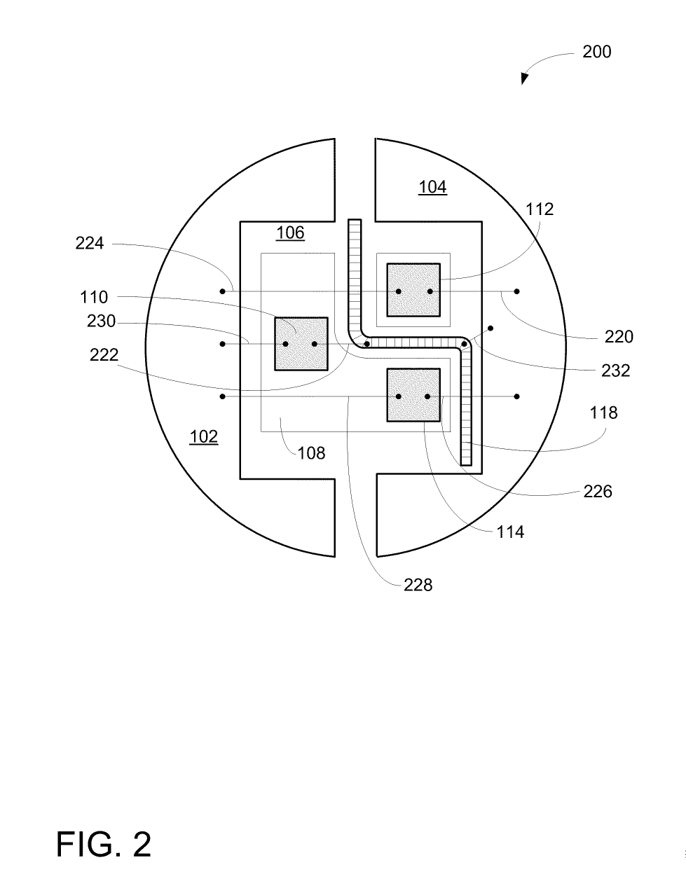

FIG. 2 is a diagram 200 illustrating a lighting system having three LED dice capable of providing reconfigurable connections in accordance with an aspect of the present invention. Diagram 200 includes an LED array, a substrate 108, a dielectric layer 106, and a metal trace 118. LED dice 110-114 are coupled to terminals or pads 102-104 using bond wires 220-230. It should be noted that the underlying concept of the exemplary aspect(s) of the present invention would not change if one or more elements (or devices) were added to or removed from system 200.

The LED array includes three (3) LED dice 110-114, wherein LED dice 110-114 are connected in three-way parallel connections using metal trace 118. Referring back to FIG. 2, a first terminal of LED die 110 is connected to a first terminal of power source 102 via bond wire 230 and a second terminal of LED die 110 is connected to metal trace 118 via bond wire 222. A first terminal of LED die 112 is connected to the first terminal of power source 102 via bond wire 224 and a second terminal of LED die 112 is connected to a second terminal of power source 104 via bond wire 220. While a second terminal of LED die 114 is connected to metal trace 118 via bond wire 226, a first terminal of LED die 114 is connected to the first terminal of power source 102 via bond wire 228. Metal trace 118 is coupled with the second terminal of power source 104 via bond wire 232. Note that the first terminal of power source 102 can be the positive potential of a power supply and the second terminal of power source 104 can be negative potential of a power supply. Diagram 200 illustrates LED dice in the LED array is configured in three (3) strings in parallel wherein each string contains one LED die.

An advantage of using a metal trace is to permit reconfiguration of connectivity of LED dice in accordance with the customer's specifications while the components such as substrates and metal trace(s) are pre-fabricated.

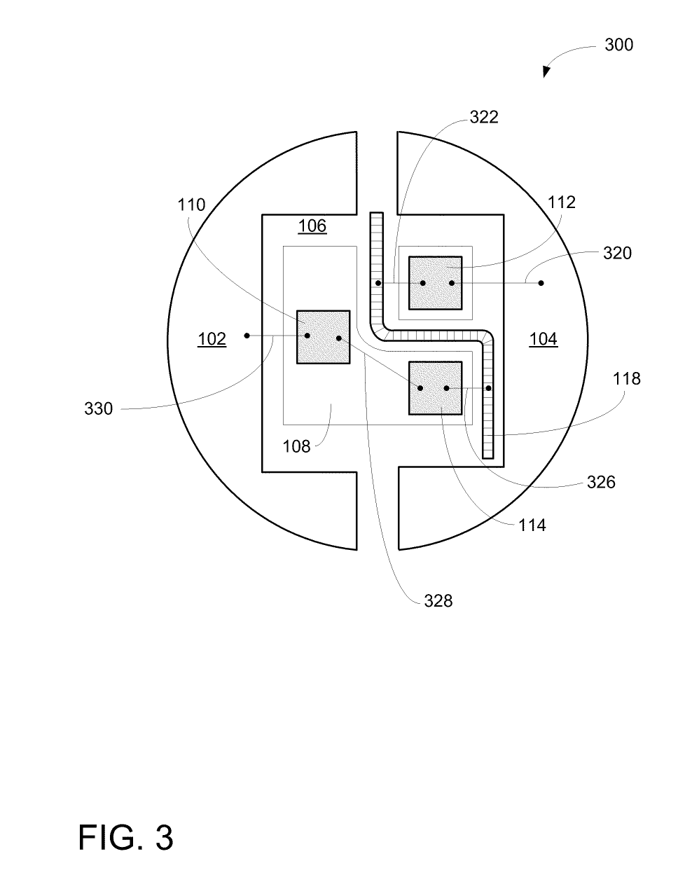

FIG. 3 is a diagram 300 illustrating a lighting system having three (3) LED dice connected in series via a metal trace in accordance with an aspect of the present invention. Diagram 300 includes an LED array, a substrate 108, a patterned dielectric layer 106, and a metal trace 118. LED dice 110-114 coupled to terminals or pads 102-104 using bond wires 320-330. The LED array includes three (3) LED dice 110-114, wherein LED dice 110-114 are connected in series using metal trace 118.

Referring back to FIG. 3, a first terminal of LED die 110 is connected to a first terminal of power source 102 via bond wire 330 and a second terminal of LED die 110 is connected to a first terminal of LED die 114 via bond wire 328. A second terminal of LED die 114 is connected to metal trace 118 via bond wire 326. A first terminal of LED die 112 is connected to metal trace 118 via bond wire 322 and a second terminal of LED die 112 is connected to a second terminal of power source 104 via bond wire 320. Note that the first terminal of power source 102 can be the positive potential of a power supply and the second terminal of power source 104 can be negative potential of a power supply. Diagram 300 illustrates the LED array containing one (1) string of LED dice connected in series.

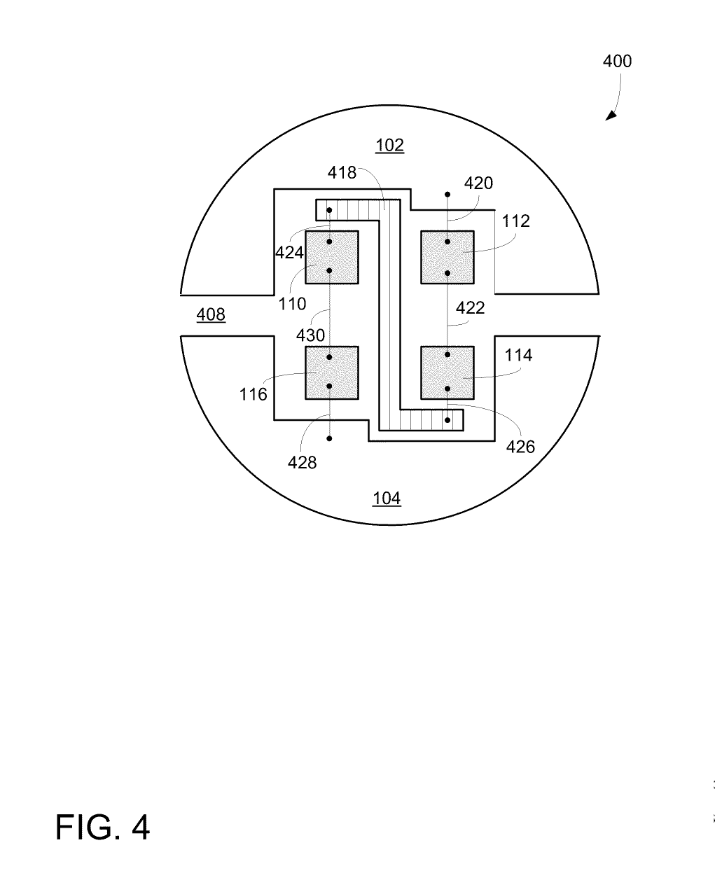

FIG. 4 is a diagram 400 illustrating a lighting system having four (4) LED dice 110-116 connected in series via a Z-shaped metal trace in accordance with an aspect of the present invention. Diagram 400 includes an LED array, a substrate 408, and a metal trace 418 wherein metal trace 418 is in a Z shape. LED dice 110-114 are coupled to terminals or pads 102-104 using bond wires 420-430. The LED array includes four (4) LED dice 110-116, wherein LED dice 110-116 are connected in series connection using metal trace 418.

Referring back to FIG. 4, a first terminal of LED die 110 is connected to metal trace 418 via bond wire 424 and a second terminal of LED die 110 is connected to a first terminal of LED die 116 via bond wire 430. While a second terminal of LED die 116 is connected to a first terminal of power source 104 via bond wire 428, a second terminal of LED die 114 is connected to metal trace 418 via bond wire 426. A first terminal of LED 114 is connected to a second terminal of LED die 112 via bond wire 422, and a first terminal of LED die 112 is connected to a second terminal of power source 102 via bond wire 420. Note that the first terminal of power source 102 can be the positive potential of a power supply and the second terminal of power source 104 can be negative potential of a power supply. Diagram 400 illustrates an LED array containing one (1) LED string of four (4) LED dice 110-116 connected in series using a Z-shaped metal trace.

In one aspect, adjacent dice in each row of a matrix or array are directly connected by bond wires between n pad(s) of one die and p pad(s) of adjacent die in series. Dice between different rows are electrically connected in series with bond wire(s) to a conductive metal trace disposed over a substrate. In an alternative aspect, adjacent dice in each column of a matrix or array are directly connected by bond wires between n pad(s) of one die and p pad(s) of adjacent die in series. The dice between different columns are electrically connected in series by bond wire(s) via a conductive metal trace situated over the substrate. It should be noted that an independent conductive metal trace situated between each row and column of LED dice organized in array can provide reconfiguring LED die connections such as in series, parallel, and/or a combination of series and parallel.

An advantage of using a Z-shaped metal trace is to provide connection pad as well as render shorter bond wires to achieve reconfigurable interconnections. Note that LED dice connected in series produce more flux for a fixed total drive current than the same number of LED dice in parallel or in series/parallel strings. It is particularly advantageous since power supplies with high current and low voltage are more expensive than those with lower current and high voltage.

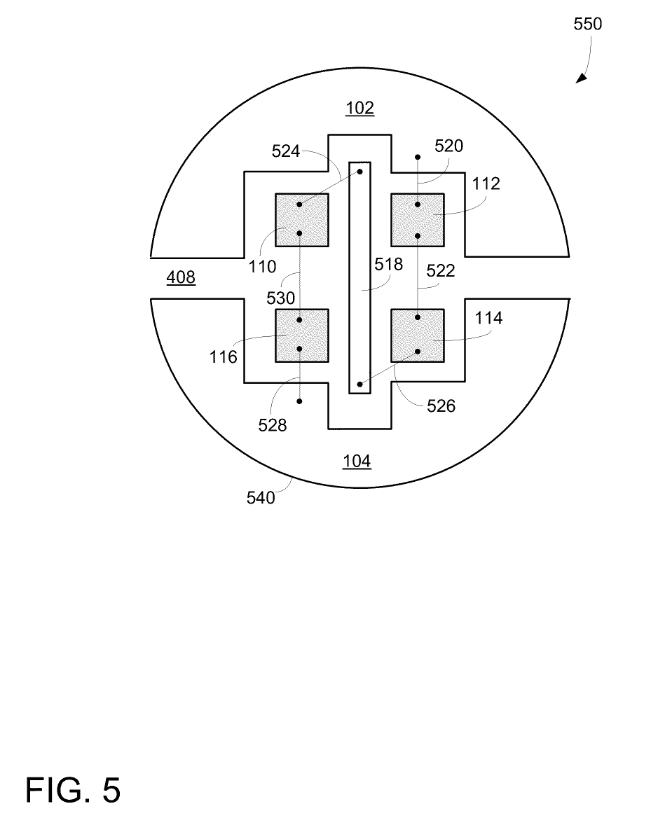

FIG. 5 is a diagram 550 illustrating a lighting system having multiple LED dice connected in series using a straight metal trace in accordance with an aspect of the present invention. Diagram 550 includes an LED array, a substrate 408, and a metal trace 518 wherein metal trace 518 is formed in an I shape or a straight line. LED dice 110-116 are coupled to terminals or pads 102-104 using bond wires 520-530. The LED array includes four (4) LED dice 110-116, wherein LED dice 110-116 are connected in series using metal trace 518.

Referring back to FIG. 5, a first terminal of LED die 110 is connected to metal trace 518 via bond wire 524 and a second terminal of LED die 110 is connected to a first terminal of LED die 116 via bond wire 530. While a second terminal of LED die 116 is connected to a first terminal of power source 104 via bond wire 528, a second terminal of LED die 114 is connected to metal trace 518 via bond wire 526. A first terminal of LED 114 is connected to a second terminal of LED die 112 via bond wire 522, and a first terminal of LED die 112 is connected to a second terminal of power source 102 via bond wire 520. Diagram 550 illustrates an LED array containing one (1) string of LED dice 110-116 using an I-shaped metal trace.

The first terminal of power source 104, in one aspect, is a substrate metallization that is connected to a positive (+) terminal of LED array. The second terminal of power source 102, on the other hand, is a substrate metallization that is connected to a negative (−) terminal of LED array. The perimeter of cavity 540 may be filled with silicone and/or phosphor encapsulation. An advantage of using an I-shaped metal trace is to provide flexible connecting pad for bond wires to achieve reconfigurable connections.

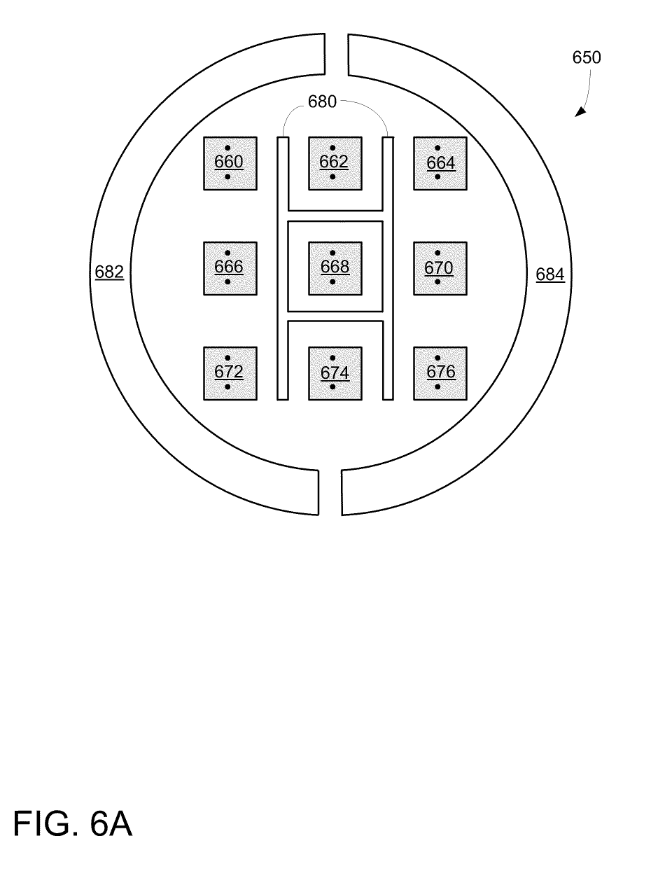

FIG. 6A is a diagram 650 illustrating an alternative metal trace configurations used in an LED light in accordance with an aspect of the present invention. Diagram 650 includes an LED array, an H-shaped metal trace 680, and electrical terminals 682-684, wherein electrical terminals 682-684 are connected to positive and negative power supply. The LED array, in one aspect, includes nine (9) LED dice 660-676 capable of converting electrical energy to optical light. H-shaped metal trace 680, in one aspect, is used for connecting pads for bond wires to provide flexible reconfigurations in connectivity.

FIG. 6B is a diagram 690 illustrating an alternative exemplary connection reconfiguration of an LED lighting device having metal traces situated every other column within an LED array in accordance with an aspect of the present invention. Diagram 690 includes an LED array and I-shaped metal traces 692 wherein the LED array includes x rows by y columns (“X×Y”) of LED dice. I-shaped metal traces 692 are used to facilitate flexible connectivity to generate different LED dice connecting configurations in accordance with one or more specifications.

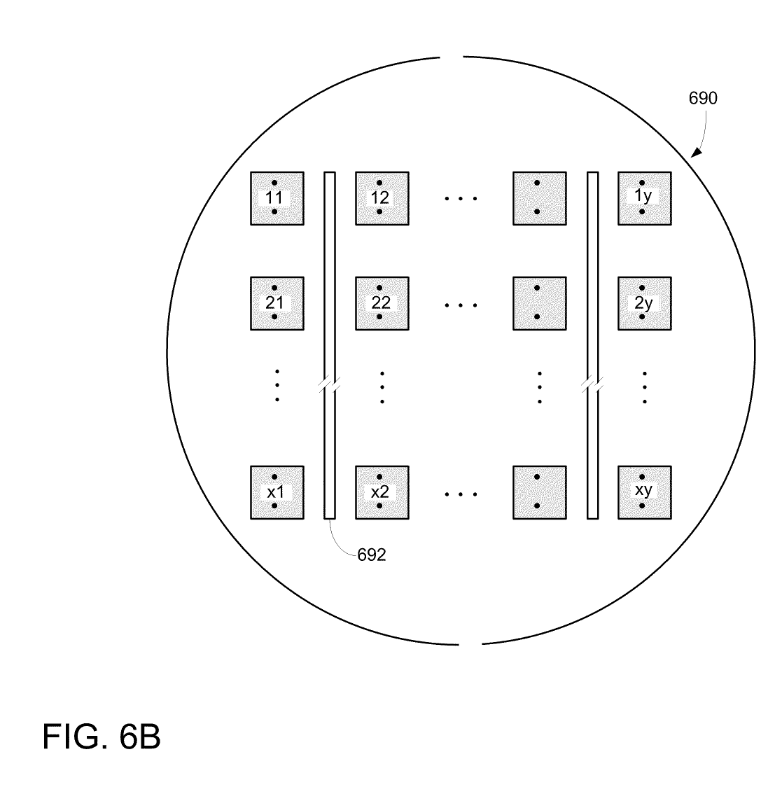

FIG. 7A illustrates images showing two LED lighting devices capable of reconfiguring connections using metal traces in accordance with an aspect of the present invention. Image 750 shows an LED lighting device including an LED array and an S-shaped metal trace 760, wherein the LED array further includes four (4) LED dice 752-758. In one aspect, the LED lighting device illustrated in image 750 has similar configuration as the device illustrated in FIG. 1. The lighting device uses metal trace 760 to form two (2) strings of LED dice in parallel wherein each string includes two LED dice.

Image 770 shows an LED lighting device including an LED array and an S-shaped metal trace 780, wherein the LED array further includes three (3) LED dice 772-776. In one aspect, lighting device illustrated in image 770 has similar configuration as the device illustrated in FIG. 2. The lighting device uses metal trace 780 to form three (3) strings of LED dice in parallel wherein each string includes one (1) LED die.

FIG. 7B illustrates images showing two LED lighting devices capable of reconfiguring alternative connections using metal traces in accordance with an aspect of the present invention. Image 786 shows an LED lighting device including an array of four LED dice configured in four (4) strings of LED dice in parallel wherein each string includes one LED die. Image 788 shows an LED lighting device including an array of four LED dice configured in one (1) string of four (4) LED dice connected in series.

FIG. 7C illustrates images showing two LED lighting devices capable of reconfiguring alternative connections using metal traces in accordance with an aspect of the present invention. Image 790 shows an LED lighting device including an array of four (4) LED dice configured in one (1) string of four (4) LED dice connected in series using an L shaped metal trace 792. Image 796 shows an LED lighting device including an array of three (3) LED dice configured in one (1) string of three (3) LED dice connected in series.

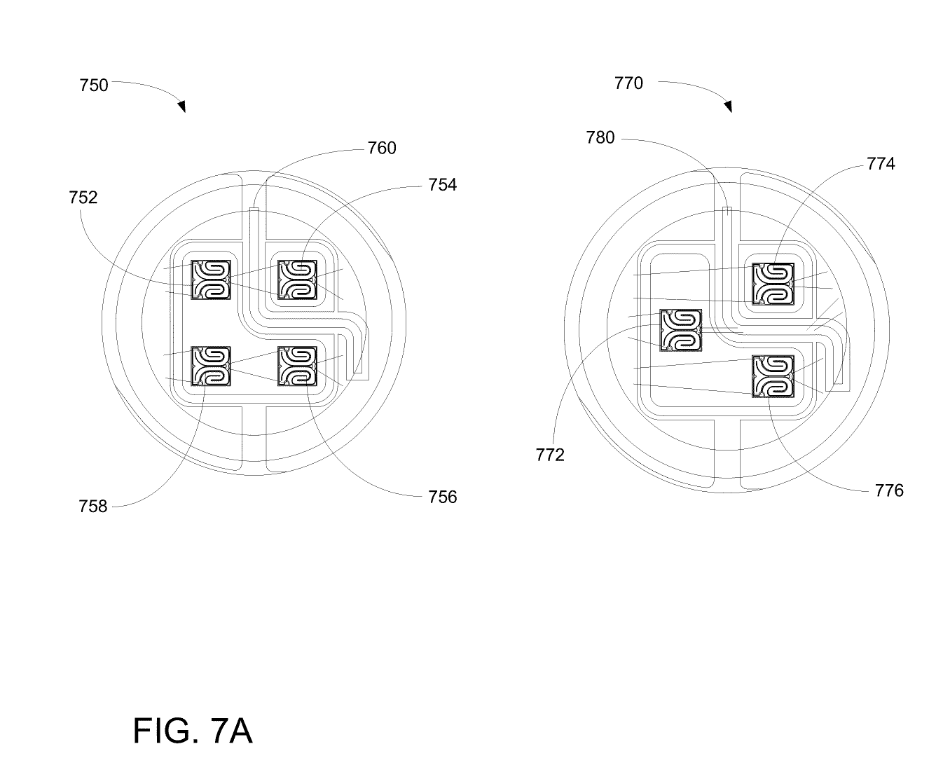

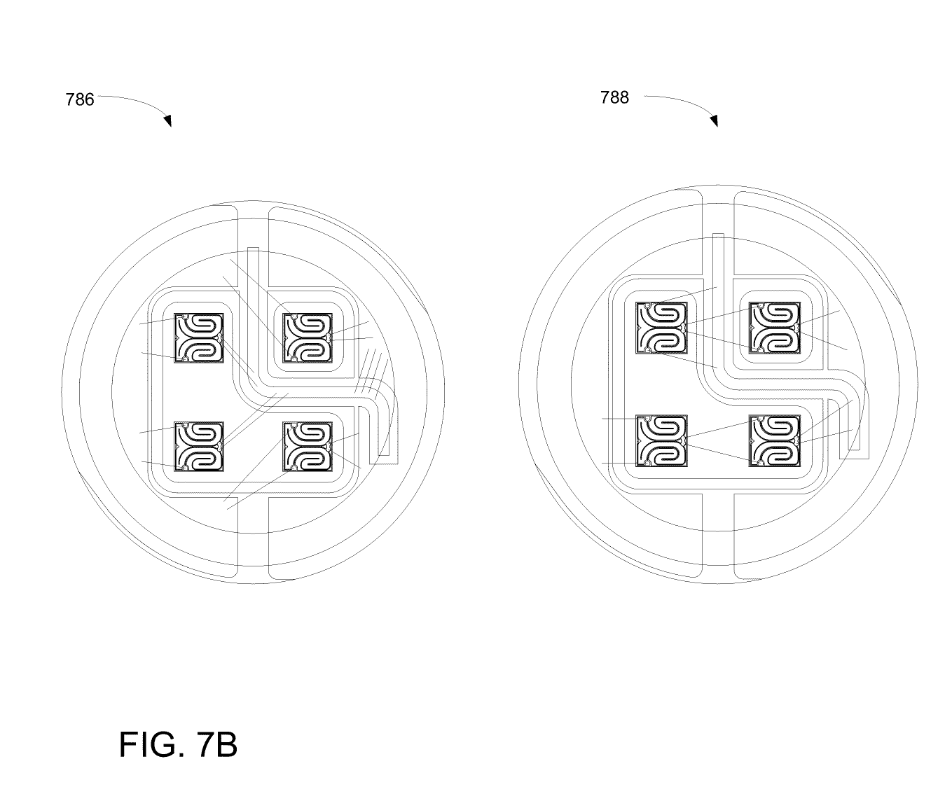

FIG. 8A is a diagram 850 illustrating an exploded view of a lighting system having an LED array using a metal trace for providing flexible LED connections in accordance with an aspect of the present invention. Diagram 850 includes a substrate or base layer 862, a patterned dielectric layer 860, a metal layer 858, a metal trace 864, a solder mask layer 856, a disk 854 including encapsulant, and a cavity ring 852. Metal layer 858 further includes a first terminal 864 and a second terminal 866 wherein metal layer 858 is a conductive layer, which can be made of copper, nickel, aluminum, gold or a combination of conductive alloy. First and second terminals 864-866 are configured to connect to negative and positive power terminals 868-870, respectively. It should be noted that the components illustrated in diagram 850 can be pre-fabricated, and the connecting configuration in the LED array can be subsequently configured according to the specification using bond wires. Note that the underlying concept of the exemplary aspect(s) of the present invention would not change if one or more components (or layers) were added to or removed from diagram 850.

FIG. 8B illustrates images of LED lighting assembly having an LED array and metal trace for facilitating flexible LED connections in accordance with an aspect of the present invention. Image 870 shows a top view of an LED lighting assembly having an LED array and a metal trace 882, wherein the LED array includes four (4) LED dice 874-880. Image 890 illustrates an isometric view of the LED lighting assembly shown in image 870. In one aspect, the connection configuration of LED dice 874-880 can be adjusted or reconfigured using bond wires via metal trace 882.

The exemplary aspect of the present invention includes various processing steps, which will be described below. The steps of the aspect may be embodied in machine or computer executable instructions. The instructions can be used to cause a general purpose or special purpose system, which is programmed with the instructions, to perform the steps of the exemplary aspect of the present invention. Alternatively, the steps of the exemplary aspect of the present invention may be performed by specific hardware components that contain hard-wired logic for performing the steps, or by any combination of programmed computer components and custom hardware components.

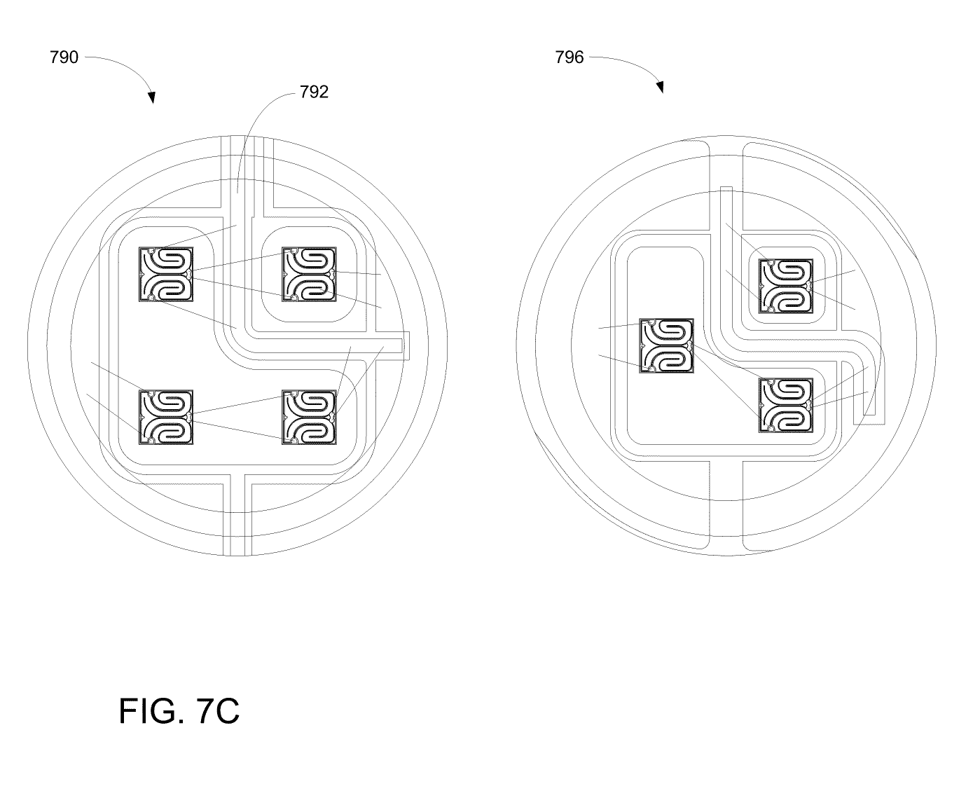

FIG. 9 is a flowchart 950 illustrating a process of fabricating a lighting device having multiple LED dice and a metal trace for reconfigurable connections in accordance with an aspect of the present invention. At block 952, a process of fabricating an LED system deposits a dielectric layer over a base layer to provide electric insulation. The base layer is a substrate that can be made of electric conductive material or dielectric material.

At block 954, a metal trace having a predefined shape is overlaid on the dielectric layer to provide electrical connections. In one aspect, the process is capable of disposing an S-shaped metal plate over the dielectric layer. In another aspect, the process is able to dispose a Z-shaped metal plate over the dielectric layer for facilitating one or more bond wire connections. In yet another aspect, the process disposes a straight metal strip over the dielectric layer to facilitate one or more bond wire connections.

At block 956, a process deposits multiple LED dice in an array formation over a base layer. In one aspect, the array formation includes four (4) LED dice. In an alternative aspect, the array formation includes three (3) LED dice.

At block 958, the process deposits LED dice in an array formation over the base layer, wherein the depositing process is able to dispose LED dice in such a way that allows the metal trace to travel through the array of LED dice. In one aspect, upon depositing an electric conductive metal layer over the dielectric layer for providing electrical power, the process connects at least a portion of the LED dice in series configurations utilizing bond wires and the metal trace. While at least a portion of the LED dice is connected in parallel connections utilizing bond wires and the metal trace, the process is capable of configuring at least a portion of the LED dice in a combination of series connections and parallel connections via utilization of bond wires and the metal trace.

At block 960, the process, in one embodiment, encloses the LED device with incapsulant and a cavity ring. Encapsulant can be a type of adhesive or non-adhesive material capable of sealing a component or components. Deposing a disk together with a cavity ring, in one example, can be the final processing stage for fabricating the LED device.

Having briefly described aspects of lighting assemblies capable of reconfiguring connections of LED dice using a metal trace in which the present invention operates, the following figures illustrate exemplary process and/or method to fabricate and package LED dies, chips, device, and/or fixtures.

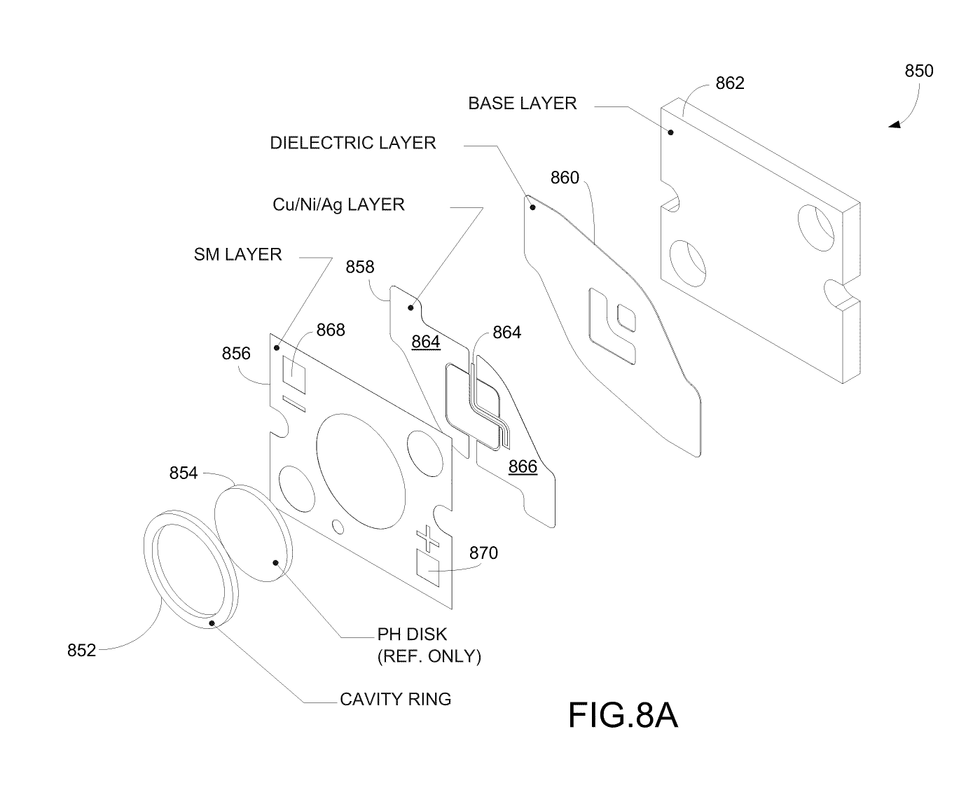

FIG. 10 is a conceptual cross-sectional view illustrating an exemplary fabrication process of an LED or LED devices. An LED is a semiconductor material impregnated, or doped, with impurities. These impurities add “electrons” or “holes” to the semiconductor, which can move in the material relatively freely. Depending on the kind of impurity, a doped region of the semiconductor can have predominantly electrons or holes, and is referred respectively as n-type or p-type semiconductor regions. Referring to FIG. 10, the LED 500 includes an n-type semiconductor region 504 and a p-type semiconductor region 508. A reverse electric field is created at the junction between the two regions, which cause the electrons and holes to move away from the junction to form an active region 506. When a forward voltage sufficient to overcome the reverse electric field is applied across the p-n junction through a pair of electrodes 510, 512, electrons and holes are forced into the active region 506 and recombine. When electrons recombine with holes, they fall to lower energy levels and release energy in the form of light.

In this example, the n-type semiconductor region 504 is formed on a substrate 502 and the p-type semiconductor region 508 is formed on the active layer 506, however, the regions may be reversed. That is, the p-type semiconductor region 508 may be formed on the substrate 502 and the n-type semiconductor region 504 may formed on the active layer 506. As those skilled in the art will readily appreciate, the various concepts described throughout this disclosure may be extended to any suitable layered structure. Additional layers or regions (not shown) may also be included in the LED 500, including but not limited to buffer, nucleation, contact and current spreading layers or regions, as well as light extraction layers.

The p-type semiconductor region 508 is exposed at the top surface, and therefore, the p-type electrode 512 may be readily formed thereon. However, the n-type semiconductor region 504 is buried beneath the p-type semiconductor layer 508 and the active layer 506. Accordingly, to form the n-type electrode 510 on the n-type semiconductor region 504, a cutout area or “mesa” is formed by removing a portion of the active layer 506 and the p-type semiconductor region 508 by means well known in the art to expose the n-type semiconductor layer 504 there beneath. After this portion is removed, the n-type electrode 510 may be formed.

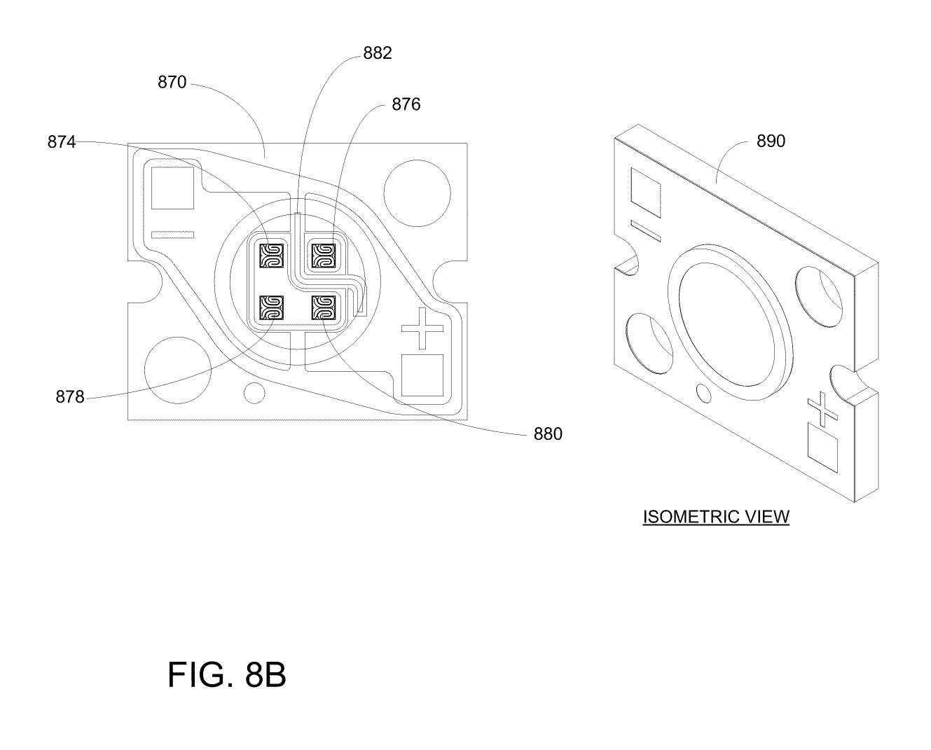

FIG. 11 is a conceptual cross-sectional view illustrating an example of an LED with a phosphor layer. In this example, a phosphor layer 602 is formed on the top surface of the LED 500 by means well known in the art. The phosphor layer 602 converts a portion of the light emitted by the LED 500 to light having a different spectrum. A white LED light source can be constructed by using an LED that emits light in the blue region of the spectrum and a phosphor that converts blue light to yellow light. A white light source is well suited as a replacement lamp for conventional luminaries; however, the invention may be practiced with other LED and phosphor combinations to produce different color lights. The phosphor layer 602 may include, by way of example, phosphor particles suspended in a carrier or be constructed from a soluble phosphor that is dissolved in the carrier.

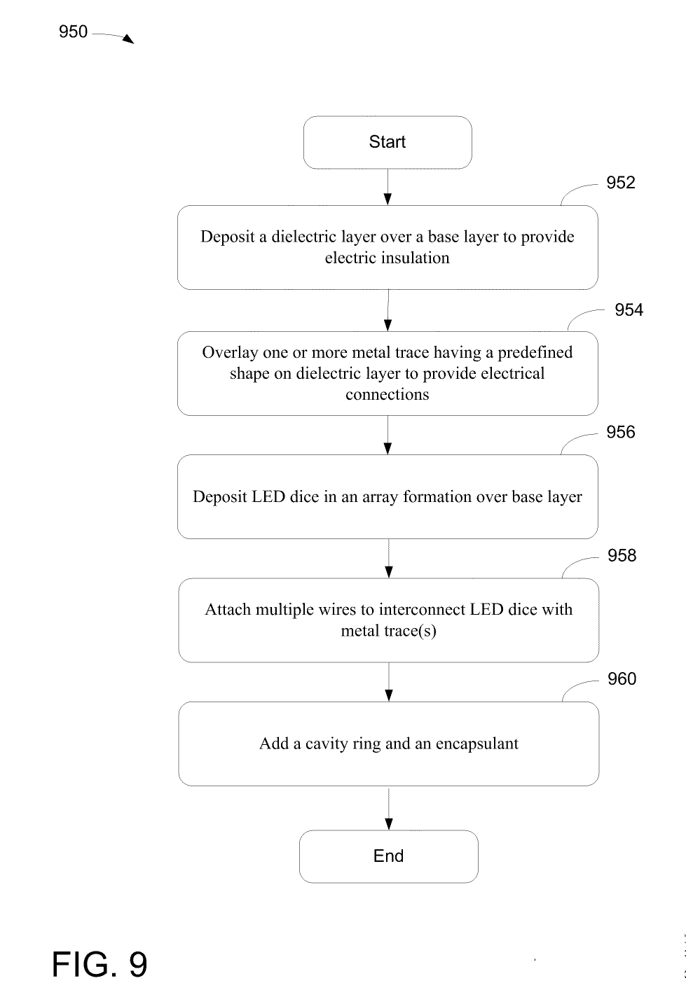

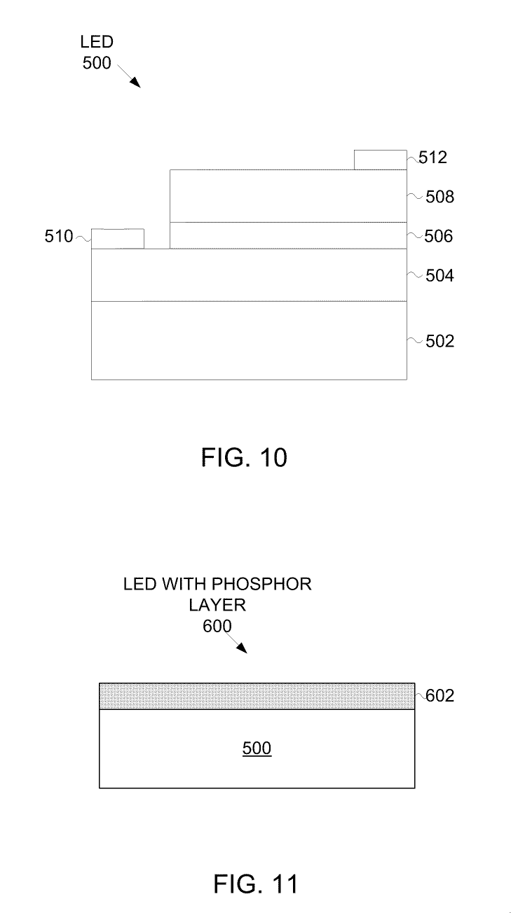

In a configuration of LED luminaries, an LED array may be used to provide increased luminance. FIG. 12A is a conceptual top view illustrating an example of an LED array, and FIG. 12B is a conceptual cross-sectional view of the LED array of FIG. 12A. In this example, a number of phosphor-coated LEDs 600 may be formed on a substrate 702. The bond wires (not shown) extending from the LEDs 600 may be connected to traces (not shown) on the surface of the substrate 702, which connect the LEDs 600 in a parallel and/or series fashion. In some embodiments, the LEDs 600 may be connected in parallel streams of series LEDs with a current limiting resistor (not shown) in each stream. The substrate 702 may be any suitable material that can provide support to the LEDs 600 and can be mounted within a light fixture (not shown).

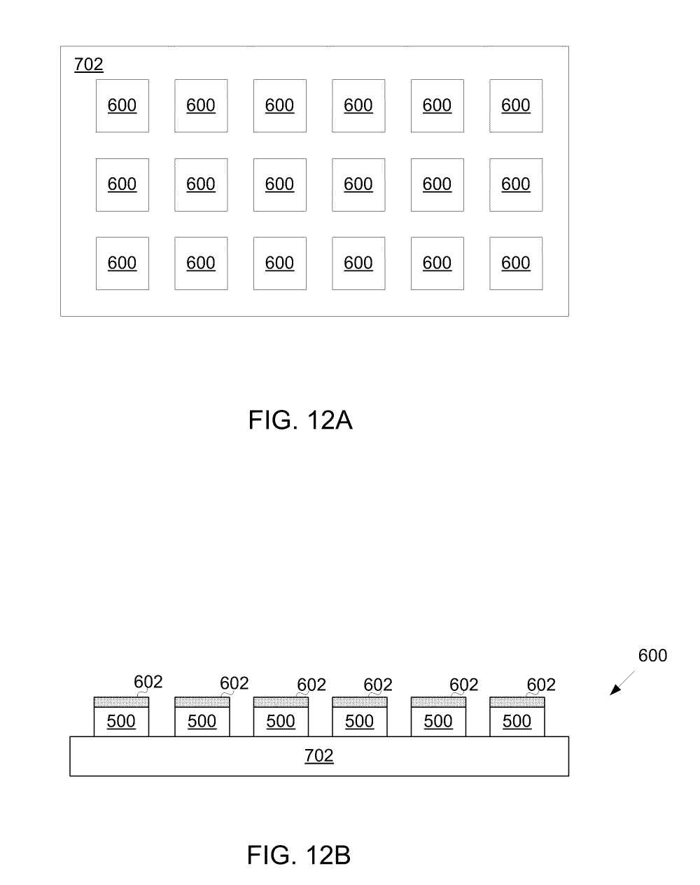

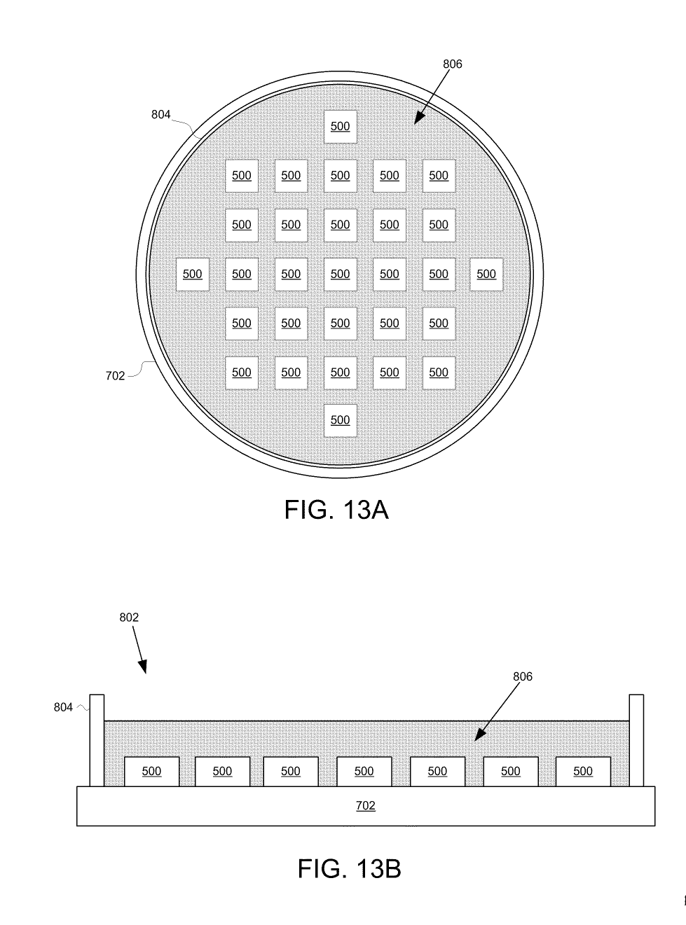

FIG. 13A is a conceptual top view illustrating an example of an alternative configuration of an LED array, and FIG. 13B is a conceptual cross-sectional view of the LED array of FIG. 13A. In a manner similar to that described in connection with FIGS. 12A and 12B, a substrate 702 designed for mounting in a light fixture (not shown) may be used to support an array of LEDs 500. However, in this configuration, a phosphor layer is not formed on each individual LED. Instead, phosphor 806 is deposited within a cavity 802 bounded by an annular ring 804 that extends circumferentially around the outer surface of the substrate 702. The annular ring 804 may be formed by boring a cylindrical hole in a material that forms the substrate 702. Alternatively, the substrate 702 and the annular ring 804 may be formed with a suitable mold, or the annular ring 804 may be formed separately from the substrate 702 and attached to the substrate using an adhesive or other suitable means. In the latter configuration, the annular ring 804 is generally attached to the substrate 702 before the LEDs 500, however, in some configurations, the LEDs may be attached first. Once the LEDs 500 and the annular ring 804 are attached to the substrate 702, a suspension of phosphor particles in a carrier may be introduced into the cavity 802. The carrier material may be an epoxy or silicone; however, carriers based on other materials may also be used. The carrier material may be cured to produce a solid material in which the phosphor particles are immobilized.

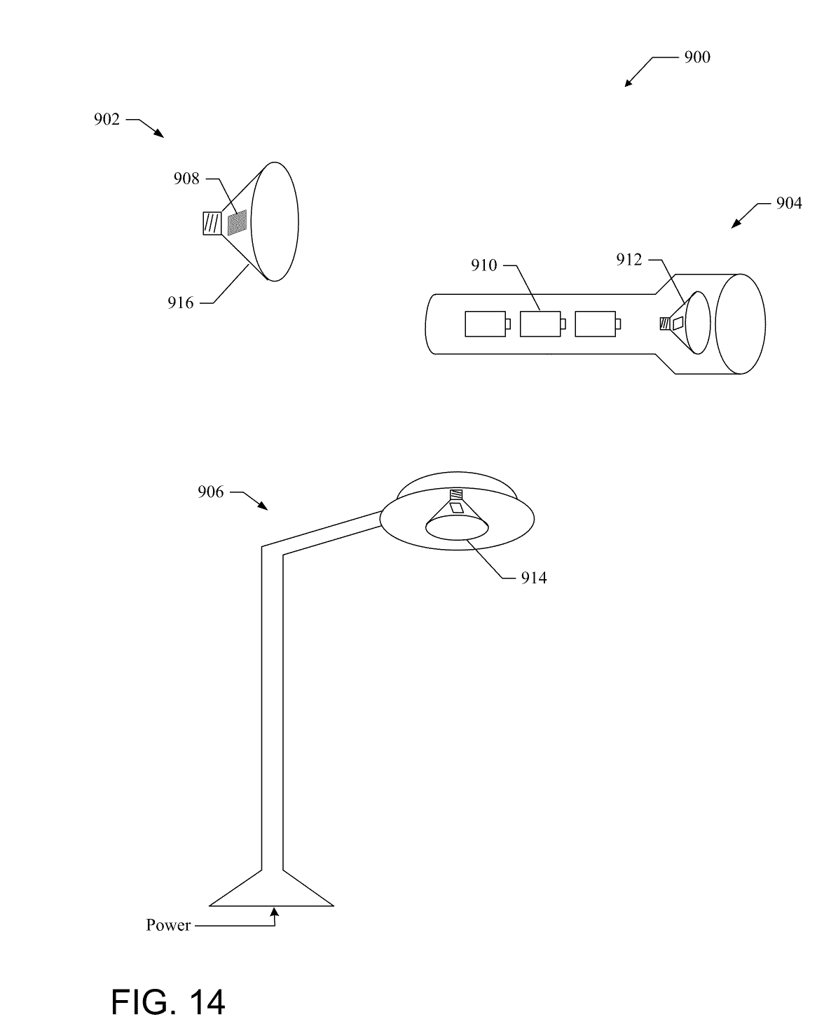

FIG. 14 shows exemplary devices including LEDs or LED devices using metal traces in accordance with aspects of the present invention. The devices 900 include a lamp 902, an illumination device 904, and a street light 906. Each of the devices shown in FIG. 14 includes at least an LED or an LED device using metal traces as described herein. For example, lamp 902 includes a package 916 and an LED 908, in which LED 908 employs one or more metal traces to provide flexible connections. Lamp 902 may be used for any type of general illumination. For example, lamp 902 may be used in an automobile headlamp, street light, overhead light, or in any other general illumination application. Illumination device 904 includes a power source 910 that is electrically coupled to a lamp 912, which may be configured as lamp 902. In an aspect, power source 910 may be batteries or any other suitable type of power source, such as a solar cell. Street light 906 includes a power source connected to a lamp 914, which may be configured as lamp 902. It should be noted that aspects of the LED described herein are suitable for use with virtually any type of LED assembly, which in turn may be used in any type of illumination device and are not limited to the devices shown in FIG. 14.

The various aspects of this disclosure are provided to enable one of ordinary skill in the art to practice the present invention. Various modifications to aspects presented throughout this disclosure will be readily apparent to those skilled in the art, and the concepts disclosed herein may be extended to other LED lamp configurations regardless of the shape or diameter of the glass enclosure and the base and the arrangement of electrical contacts on the lamp. Thus, the claims are not intended to be limited to the various aspects of this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

1. A light-emitting device, comprising:
a dielectric layer disposed over a substrate and configured to provide electric insulation;
a light emitting diode (“LED”) array having a plurality of LED dice disposed over the substrate for generating light; and
a metal trace disposed over the dielectric layer and configured to provide electric connections, wherein the metal trace has a predefined shape configured to travel through the LED array.

2. The device of claim 1, further comprising a metal layer disposed over the dielectric layer and configured to conduct electrical power.

3. The device of claim 1, wherein the metal trace facilitates LED dice configurations utilizing bond wires.

4. The device of claim 2, wherein the metal trace is capable of configuring at least a portion of the LED dice in a series configuration.

5. The device of claim 2, wherein the metal trace is capable of configuring at least a portion of the LED dice in a parallel connection.

6. The device of claim 2, wherein the metal trace is capable of facilitating a combination of a series configuration of the LED dice and a parallel configuration of the LED dice.

7. The device of claim 6, wherein the metal trace is an S-shaped electrical conductive plate.

8. The device of claim 1, wherein the metal trace is a Z-shaped electrical conductive plate.

9. The device of claim 1, wherein the metal trace is a straight electrical conductive strip.

10. A method of fabricating a light emitting device, comprising:
depositing a dielectric layer over a base layer to provide electric insulation;
overlaying a metal trace having a predefined shape on the dielectric layer to provide electrical connections; and
depositing a plurality of light emitting diode (“LED”) dice in an array formation over the base layer, wherein depositing the plurality of LED dice includes disposing LED dice in such a way that allows the metal trace to travel through the array formation.

11. The method of claim 10, further comprising depositing an electric conductive metal layer over the dielectric layer for providing electrical power.

12. The method of claim 11, wherein overlaying a metal trace having a predefined shape on the dielectric layer further includes disposing an S-shaped metal plate over the dielectric layer.

13. The method of claim 11, wherein overlaying a metal trace having a predefined shape on the dielectric layer further includes disposing a Z-shaped metal plate over the dielectric layer for facilitating one or more bond wire connections.

14. The method of claim 11, wherein overlaying a metal trace having a predefined shape on the dielectric layer further includes disposed a straight metal strip over the dielectric layer to facilitate one or more bond wire connections.

15. The method of claim 10, further comprising configuring at least a portion of the plurality of LED dice in a series configuration utilizing bond wires and the metal trace.

16. The method of claim 10, further comprising configuring at least a portion of the plurality of LED dice in a parallel connection utilizing bond wires and the metal trace.

17. The method of claim 10, further comprising configuring at least a portion of the plurality of LED dice in a combination of series connections and parallel connections via utilization of bond wires and the metal trace.

18. A light emitting diode (“LED”) lamp, comprising:
a package; and
an LED apparatus coupled to the package and including:
a dielectric layer disposed over a substrate and configured to provide electric insulation;
a light emitting diode (“LED”) array having a plurality of LED dice disposed over the substrate for generating light; and
a metal trace disposed over the dielectric layer and configured to provide electric connections, wherein the metal trace has a predefined shape configured to travel through the LED array.

19. The lamp of claim 18, wherein the LED apparatus further including a metal layer disposed over the dielectric layer and configured to conduct electrical power.

20. The lamp of claim 19, wherein the metal trace is able to configure the LED dice in one or more connecting configurations utilizing bond wires.

21-25. (canceled)
